(19) United States
(12) Patent Application Publication
(10) Pub. No.: US 2026/0276740 A1
(43) Pub. Date: Sep. 17, 2026

(54) ECU POWER CABLE FAULT DETECTION

(71) Applicant: Cummins Inc., Columbus, IN (US)

(72) Inventors: Sarang Gupta, Nagpur (IN); Ashish |jantkar, Pune (IN); William D. Meyer, Columbus, IN (US); Surabhi Kushwaha, Kanpur (IN)

(21) Appl. No.: 19/077,581

(22) Filed: Mar. 12, 2025

(51) Int. Cl. G01R 31/58; G01K 1/02; G01K 3/14; G01K 7/22; H02H 5/04

(52) U.S. Cl. CPC G01R 31/58; G01K 1/026; G01K 3/14; G01K 7/22; H02H 5/04

(57) ABSTRACT

An electronic control unit (ECU) includes a housing, a circuit board disposed in the housing, and a power terminal conductively coupled with the circuit board and accessible from an exterior of the housing. A power cable is operatively coupled with the power terminal and one of a power supply and a load. The power cable includes a terminal connector crimped about a jacketed conductor and conductively coupled with the power terminal. A first temperature sensor is configured to sense a first temperature. A second temperature sensor configured to sense a second temperature. A diagnostic circuit is configured to indicate presence or absence of a fault of the power cable in response to the first temperature and the second temperature. A controller is configured to change operation of the ECU in response to output of the second comparator.

### TECHNICAL FIELD

The present application relates to detection of faults in power cables for electronic control units (ECU) and related apparatuses, systems and techniques.

### BACKGROUND

ECU power cables may experience a number of faults as a result of material aging, temperature cycling, noise, vibration, harshness, and other environment or operating conditions. Some such cables may experience faults including deterioration of a mechanical and/or conductive connection between a cable conductor and a terminal connector of the cable configured to operatively coupled with an ECU, among other faults. A number of efforts have been made to identify faults in ECU power cables. Existing approaches suffer from a number of disadvantages, drawbacks, problems, and shortcomings including the need for high degrees of human intervention and external test equipment as well as those respecting complexity, cost, and reliability, among others. There remains a significant need for the unique apparatuses, processes, and systems disclosed herein.

### DISCLOSURE OF EXAMPLE EMBODIMENTS

For the purposes of clearly, concisely, and exactly describing example embodiments of the present disclosure, the manner, and process of making and using the same, and to enable the practice, making and use of the same, reference will now be made to certain example embodiments, including those illustrated in the figures, and specific language will be used to describe the same. It shall nevertheless be understood that no limitation of the scope of the invention is thereby created, and that the invention as set forth in the claims following this disclosure includes and protects such alterations, modifications, and further applications of the example embodiments as would occur to one skilled in the art with the benefit of the present disclosure.

### SUMMARY OF THE DISCLOSURE

Some embodiments include unique ECU power cable fault detection apparatus. Some embodiments include unique ECU power cable fault detection systems. Some embodiments include unique ECU power cable fault detection processes. Further embodiments, forms, objects, features, advantages, aspects, and benefits shall become apparent from the following description and drawings.

### BRIEF DESCRIPTION OF THE DRAWINGS

FIG. 1 is a schematic diagram illustrating certain aspects of an example powertrain system.

FIG. 2 is a side view schematic diagram illustrating certain aspects of an example electronic control system.

FIG. 3 is a top view schematic diagram illustrating certain aspects of a circuit board of the example electronic control system pf FIG. 2.

FIG. 4 is circuit diagram illustrating certain aspects of example circuitry.

FIG. 5 is a flow diagram illustrating certain aspects of an example process.

### DETAILED DESCRIPTION OF EXAMPLE EMBODIMENTS

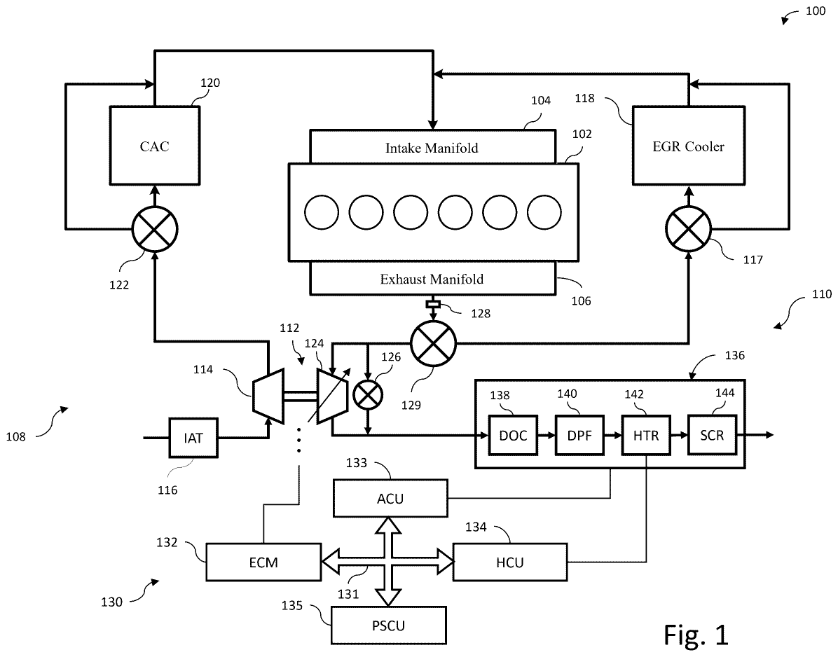

With reference to FIG. 1, there is illustrated an example powertrain system 100 (also referred to herein as system 100) including a prime mover in the form of an internal combustion engine (ICE) 102. System 100 may be provide in a number of forms including, for example, in the form of a vehicle or vehicle powertrain system (e.g., an on-highway vehicle or vehicle powertrain system or an off-highway vehicle or vehicle powertrain system), a work machine or work machine powertrain system, a genset or genset powertrain system, or a hydraulic fracturing rig or hydraulic fracturing rig powertrain system, to name several non-limiting examples. In shall be appreciated that system 100 may include a number of other components as will occur to one of skill in the art with the benefit and insight of the present disclosure. Furthermore, while engine 102 is provided as a prime mover of system 100 in the illustrated embodiment, other embodiments may comprise other types of prime movers, for example, battery electric drive systems, hybrid ICE-battery electric systems, a fuel cell electric drive system, or prime mover systems comprising combinations of the foregoing and/or other types of prime mover system as will occur to one of skill in the art with the benefit and insight of the present disclosure.

System 100 includes an intake system 108 and an exhaust system 110. The engine 102 is in fluid communication with the intake system 108 through which charge air enters an intake manifold 104 and is also in fluid communication with the exhaust system 110, through which exhaust gas resulting from combustion exits by way of an exhaust manifold 106. The engine 102 includes a number of cylinders (e.g., cylinders 1 through 6) forming combustion chambers in which a charge flow mixture of fuel and air is combusted. For example, the energy released by combustion powers the engine 102 via pistons in the cylinders connected to a crankshaft. Intake valves control the admission of charge air into the cylinders, and exhaust valves control the outflow of exhaust gas through exhaust manifold 106 and ultimately to the atmosphere. It shall be appreciated that the exhaust manifold 106 may be a single manifold or multiple exhaust manifolds.

The turbocharger 112 includes a compressor 114 configured to receive filtered intake air via an intake air throttle (IAT) 116 of the intake system 108 and operable to compress ambient air before the ambient air enters the intake manifold 104 of the engine 102 at increased pressure. The air from the compressor 114 is pumped through the intake system 108, to the intake manifold 104, and into the cylinders of the engine 102, typically producing torque on the crankshaft. IAT 116 is flow coupled with a charge air cooler (CAC) 120 which is operable to cool the charge flow provided to the intake manifold 104. The intake system 108 also includes a CAC bypass valve 122 which can be opened to route a portion or all of the charge flow to bypass the CAC 120. Adjusting the bypass position of the CAC bypass valve 122 increasingly raises the temperature of the gas returned to the intake manifold 104.

It is contemplated that in system 100, the turbocharger 112 may be a variable geometry turbocharger (VGT) or a fixed geometry turbocharger. A variable geometry turbine allows significant flexibility over the pressure ratio across the turbine. In diesel engines, for example, this flexibility can be used for improving low speed torque characteristics, reducing turbocharger lag and driving exhaust gas recirculation flow. In an example embodiment, the VGT 124 can be adjusted to increase engine load and thereby configured to increase exhaust gas temperature. System 100 also includes a turbine bypass valve 126 to bypass the turbocharger 112. Since cooler ambient air is introduced at the turbocharger 112, opening the turbine bypass valve 126 allows for the turbocharger 112 to be bypassed and maintain a higher intake air temperature at the intake manifold 104.

The exhaust system 110 includes an exhaust gas temperature sensor 128 to sense the temperature of the gas exiting the exhaust manifold 106. The exhaust system 110 includes an exhaust gas recirculation (EGR) valve 129 which recirculates a portion of exhaust gas from the exhaust manifold 106 back to the intake manifold 104. The exhaust system 110 includes an EGR cooler (EGR-C) 118 which cools the gas exiting the exhaust manifold 106 before the gas returns to the intake manifold 104. The exhaust system 110 may also include an EGR-C bypass valve 117 which can be opened to route a portion or all of the recirculated exhaust gas from the exhaust manifold 106 to bypass the EGR-C 118. By increasing the amount of gas that bypasses the EGR-C 118, the temperature of the gas returning to the intake manifold 104 is increased. It shall be appreciated that the intake system 108 and/or the exhaust system 110 may further include various components not shown, such as additional coolers, valves, bypasses, intake throttle valves, exhaust throttle valves, and/or compressor bypass valves, for example.

System 100 includes an exhaust aftertreatment (AT) system 136 which includes a diesel oxidation catalyst (DOC) 138, a diesel particulate filter (DPF) 140, aftertreatment (AT) heater 142, and a selective catalytic reduction (SCR) 144. In the example embodiment, the AT heater 142 is optionally included in the AT system 136 to increase the temperature of the exhaust gas provided to the SCR 144 within the AT system 136. It should be noted that AT heater 142 can include one or more electric heaters distributed at various locations at, on, within, or upstream of SCR 144 or other catalyst elements of AT system 136.

System 100 includes an electronic control system (ECS) 130. In the illustrated embodiment, ECS 130 includes a plurality of electronic control units (ECU) including an engine control module (ECM) 132, an aftertreatment control unit (ACU) 133, a heater control unit (HCU) 134, and power system control unit (PSCU) 135 which are operatively communicatively coupled with one another via one or more datalinks 131 which may comprise one or more controller area networks (CAN) and/or other types of datalinks. System 100 may include a number of other control units and controller as will occur to one of skill in the art with the benefit and insight of the present disclosure.

ECM 132 is operatively communicatively coupled with and configured and operable to control operation of and/or receive inputs from actuators, controllers, devices, sensors, and/or other components of system 100 including, for example, a number of the aforementioned features of system 100.

HCU 134 is operatively coupled with and configured and operable to control operation of and/or receive inputs from AT heater 142. It shall be appreciated that various communications hardware and protocols may be utilized to implement, such as one or more controller area networks (CAN) or other communications components.

PSCU 135 operatively communicatively coupled with and configured and operable to control operation of and/or receive inputs from an electrical power system of system 100 such as, for example, a motor generator system, a battery system, or other types of electrical power systems.

ECM 132, ACU 133, HCU 134, PSCU 135, and other components of ECS 130 may include one or more programmable controllers of a solid-state, integrated circuit type, and one or more non-transitory memory media configured to store instructions executable by the one or more microcontrollers. For purposes of the present application the term controller shall be understood to encompass microcontrollers, microprocessors, application specific integrated circuits (ASIC), other types of integrated circuit processors, field programmable gate arrays (FPGA), graphic processing units (GUP), and combinations thereof.

ECM 132, ACU 133, HCU 134, PSCU 135, and other components of ECS 130 may be implemented in any of a number of ways that combine or distribute the control function across one or more control units in various manners. The ECS 130 may execute operating logic that defines various control, management, and/or regulation functions. This operating logic may be in the form of dedicated hardware, such as a hardwired state machine, analog calculating machine, programming instructions, and/or a different form as would occur to those skilled in the art. The ECS 130 may be provided as a single component or a collection of operatively coupled components; and may be comprised of digital circuitry, analog circuitry, or a hybrid combination of both of these types. When of a multi-component form, the ECS 130 may have one or more components remotely located relative to the others in a distributed arrangement. The ECS 130 can include multiple processing units arranged to operate independently, in a pipeline processing arrangement, in a parallel processing arrangement, or the like. It shall be further appreciated that the ECS 130 and/or any of its constituent components may include one or more signal conditioners, modulators, demodulators, Arithmetic Logic Units (ALUs), Central Processing Units (CPUs), limiters, oscillators, control clocks, amplifiers, signal conditioners, filters, format converters, communication ports, clamps, delay devices, memory devices, Analog to Digital (A/D) converters, Digital to Analog (D/A) converters, and/or different circuitry or components as would occur to those skilled in the art to perform the desired communications.

ECM 132, ACU 133, HCU 134, PSCU 135, and other components of ECS 130 may include one or more non-transitory memory devices configured to store instructions in memory which are readable and executable by a controller to control operation of engine 102 as described herein. Certain control operations described herein include operations to determine one or more parameters. ECM 132, ACU 133, HCU 134, PSCU 135, and other components of ECS 130 may be configured to determine and may perform acts of determining in a number of manners, for example, by calculating or computing a value, obtaining a value from a lookup table or using a lookup operation, receiving values from a datalink or network communication, receiving an electronic signal (e.g., a voltage, frequency, current, or pulse-width modulation (PWM) signal) indicative of the value, receiving a parameter indicative of the value, reading the value from a memory location on a computer-readable medium, receiving the value as a run-time parameter, and/or by receiving a value by which the interpreted parameter can be calculated, and/or by referencing a default value that is interpreted to be the parameter value.

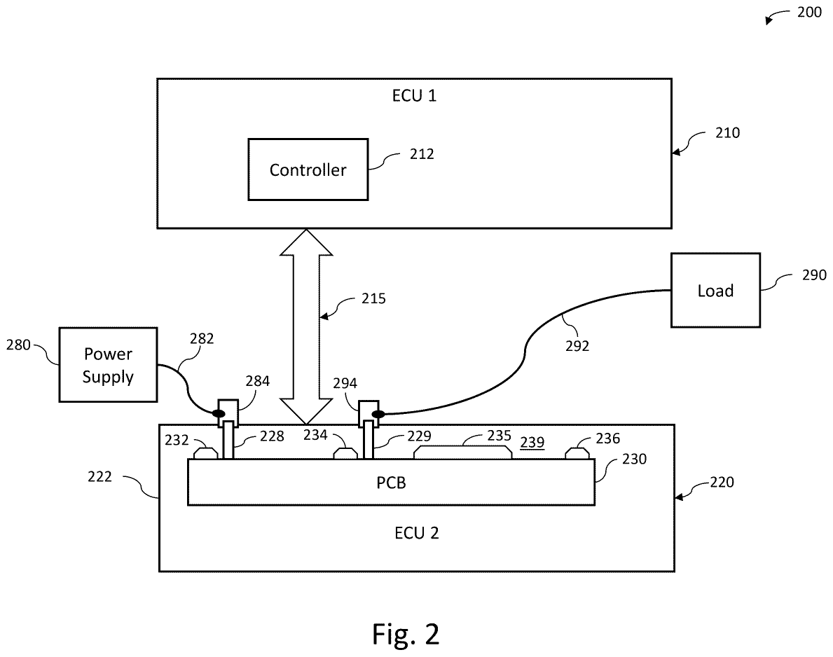

With reference to FIG. 2, there is illustrated electronic control system 200 (also referred to herein as system 200). It shall be appreciated that system 200 may be configured and provided as one implementation of certain aspects of ECS 130 or another electronic control system according to the present disclosure. System 200 includes electronic control unit (ECU) 210 and an electronic control unit (ECU) 220. ECU 210 and ECU 220 are communicatively coupled with one another via one or more datalinks 215 which may comprise one or more controller area networks (CAN) and/or other types of datalinks.

ECU 220 may be configured and provided as HCU 134, another ECU of ECS 130, or another ECU of another system. ECU 210 may be configured provided as ECM 132, another ECU of ECS 130, or another ECU of another system. In other embodiments, system 200 may be configured provided in a variety of other forms and in connection with a variety of other electronic control systems.

ECU 220 includes housing 222 which houses a number of electronic components including circuit board 230 which is disposed in housing 222. Circuit board 230 is provided with and operably coupled with a plurality of electronic components.

Power input terminal 228 (also referred to herein as terminal 228) is conductively coupled with circuit board 230 and is accessible from an exterior of housing 222, for example, by extending through housing 222 or via an access aperture, port, or socket provided in housing 222. Terminal 228 may comprise a single component or multiple components operatively coupled with one another.

Power cable to 282 is operatively coupled with terminal 228 and power supply 280 and includes a terminal connector 284 that is conductively coupled with terminal 228 and is mechanically and conductively coupled with a jacketed conductor of power cable 282, for example, by being crimped about the jacketed conductor, press fit with the connector, or by other mechanical and conductive coupling as will occur to one of skill in the art with the benefit and insight of the present disclosure.

Power output terminal 229 (also referred to herein as terminal 229) is conductively coupled with circuit board 230. Terminal 229 is accessible from an exterior of housing 222, for example, by extending through housing 222 or via an access aperture, port, or socket provided in housing 222. Terminal 229 may comprise a single component or multiple components operatively coupled with one another.

Power cable to 292 is operatively coupled with terminal 229 and a load 290 and includes a terminal connector 294 which is conductively coupled with terminal 229 and is mechanically and conductively coupled with a jacketed conductor of power cable 292, for example, by being crimped about, stamp fit to, or press fit with the jacketed conductor, or by other mechanical and conductive coupling as will occur to one of skill in the art with the benefit and insight of the present disclosure.

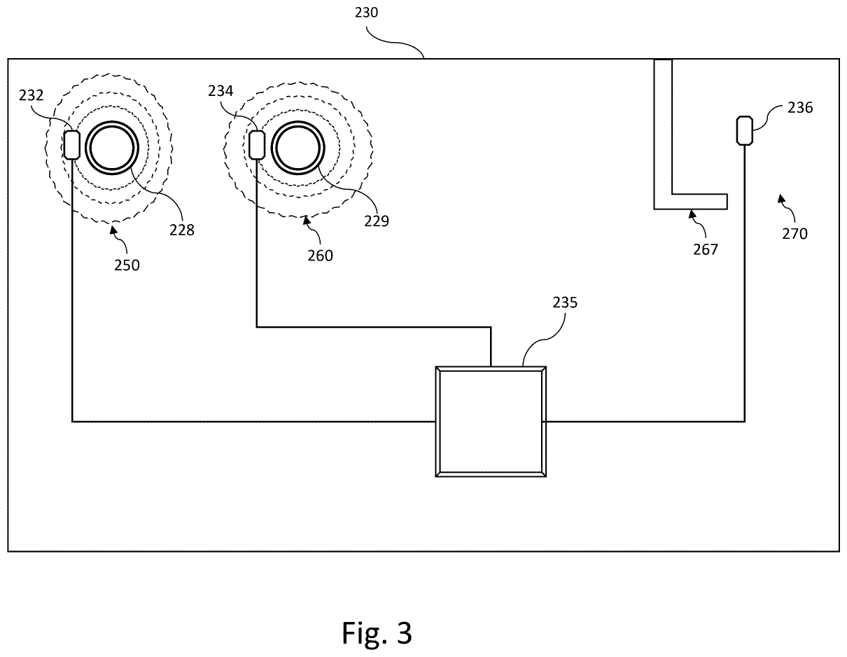

Temperature sensor 232 is operatively coupled with circuit board 230 and is positioned and configured to sense a temperature indicative of the temperature of terminal 228. It shall be appreciated that a temperature indicative of the temperature of terminal 228 refers to and includes the temperature of terminal 228 as well as temperatures of portions or components of circuit board and/or power cable 282 which are closely thermally coupled with terminal 228. Such thermal coupling may be present, for example, in regions of PCB surrounding terminal 228 which may be identified as hot spots by thermal imaging during operation of system 200 or thermal modeling of such operation. As illustrated in FIG. 3, for example, temperature sensor 232 may be positioned in region 250 surrounding terminal 228. Region 250 depicts a gradient of thermal coupling between circuit board 230 and terminal 228 as a set of ring-like regions surrounding terminal 228 with the gradient decreasing with distance from terminal 228 and may be considered one example of a hot spot of circuit board 230.

FIG. 3 illustrates one example of positioning or providing temperature sensor 232 proximate terminal 228. Such proximate positioning may extend to any region of circuit board 230 or structures coupled therewith exhibiting sufficient thermal coupling with terminal 228 to reliably indicate a temperature of, associated with, or correlated with terminal 228. It shall be appreciated that a region of circuit board 230 adjoining or adjacent terminal 228 may be preferred as it will generally exhibit higher degrees of thermal coupling than other proximate positioning, but that such other proximate positioning may be utilized in some embodiments.

Temperature sensor 234 is operatively coupled with circuit board 230 and is positioned and configured to sense a temperature indicative of the temperature of terminal 229. It shall be appreciated that a temperature indicative of the temperature of terminal 229 refers to and includes the temperature of terminal 229 as well as temperatures of portions or components of circuit board and/or power cable 282 which are closely thermally coupled with terminal 229. Such thermal coupling may be present, for example, in regions of PCB surrounding terminal 229 which may be identified as hot spots by thermal imaging during operation of system 200 or thermal modeling of such operation. As illustrated in FIG. 3, for example, temperature sensor 234 may be positioned in region 250 surrounding terminal 229. Region 250 depicts a gradient of thermal coupling between circuit board 230 and terminal 229 as a set of ring-like regions surrounding terminal 229 with the gradient decreasing with distance from terminal 229 and may be considered one example of a hot spot of circuit board 230.

FIG. 3 illustrates one example of positioning or providing temperature sensor 234 proximate terminal 229. Such proximate positioning may extend to any region of circuit board 230 or structures coupled therewith exhibiting sufficient thermal coupling with terminal 229 to reliably indicate a temperature of, associated with, or correlated with terminal 229. It shall be appreciated that a region of circuit board 230 adjoining or adjacent terminal 229 may be preferred as it will generally exhibit higher degrees of thermal coupling than other proximate positioning, but that such other proximate positioning may be utilized in some embodiments.

Temperature sensor 236 is operatively coupled with circuit board 230 and is positioned and configured to sense a temperature indicative of the temperature of the operating environment 239 surrounding circuit board 230. It shall be appreciated that a temperature indicative of the temperature of the operating environment 239 surrounding circuit board 230 refers to and includes the temperature of the operating environment 239 surrounding circuit board 230 as well as temperatures of portions or components of circuit board which are closely thermally coupled with the operating environment 239 and may be less closely correlated with localized hot spots or cold spots of circuit board 230 which exhibit lesser degrees of thermal coupling with the operating environment 239. Close thermal coupling with operating environment 239 may be present, for example, in regions of PCB relatively distant from or otherwise thermally insulated from terminal 228, terminal 229, and or other hot spot or cold spot regions of circuit board 230 which may be identified by thermal imaging during operation of system 200 or thermal modeling of such operation.

As illustrated in FIG. 3, for example, temperature sensor 236 may be positioned in region 270 relatively distant from terminal 228 and terminal 229 and thereby thermally insulated from terminal 228 and terminal 229. In the illustrated example, region 270 is further thermally insulated from other by isolation feature 267 which may comprise one or more of a region of reduced or eliminated conductive tracing, a region of insulation, a physical gap, or other insulating components and structures as will occur to one of skill in the art with the benefit and insight of the present disclosure. Region 260 indicates a region of thermal coupling between circuit board 230 and the operating environment 239 surrounding circuit board 230.

FIG. 3 illustrates one example of positioning and providing temperature sensor 236 in a location suitable for sensing a temperature indicative of the temperature of the operating environment 239 surrounding circuit board 230. Such positioning may extend to any region of circuit board 230 or structures coupled therewith exhibiting sufficient thermal coupling with operating environment 239 (and/or sufficiently low thermal coupling with terminal 228, terminal 229, and or other hot spot or cold spot regions of circuit board 230) to reliably indicate a temperature of, associated with, or correlated with operating environment 239.

Diagnostic circuit 235 is operatively coupled with circuit board 230. In the illustrated example, diagnostic circuit 235 is configured and provided in the form of a microcontroller. In other embodiments diagnostic circuit 235 may be configured and provided in other forms. In some embodiments, diagnostic circuit 235 may additionally or alternatively comprise other types of discrete integrated circuit devices, for example, comparators, other types of control or processing circuitry, and combinations thereof. Diagnostic circuit 235 is configured and operable to provide an output indicative of presence or absence of a fault of power cable 282 and/or an output indicative of presence or absence of a fault of power cable 292.

Controller 212 may be implemented and provided in ECU 210, for example, in one or more microcontrollers or other integrated circuit-based controllers. While controller 212 is implemented and provided in ECU 210 in the illustrated example, other implementations are also contemplated. In some embodiments, controller 212 may be implemented and provided in whole or in part in circuitry of ECU 220, for example, diagnostic circuit 235 and/or other control circuitry. In some embodiments, controller 212 may be distributed among or across circuitry of ECU 220, circuitry of ECU 210, and/or other control units or devices.

Controller 212 is in operative communication with diagnostic circuit 235 via one or more datalinks 215. Controller 212 may be configured and operable to receive output of diagnostic circuit 235 indicative of presence or absence of a fault of power cable 282 and/or an output indicative of presence or absence of a fault of power cable 292. Controller 212 may be further configured to, in response to one or more output indicative of a fault of power cable 282 and/or power cable 292, determine, output, and/or execute one or more fault responses. Such fault responses may include, for example, derating power operation of ECU 220 to decrease power flow through power cable 282 and/or power cable 292, disabling, disconnecting, or shutting down ECU 220 or one or more components of circuit board 230, or combinations thereof.

In some embodiments, controller 212 may be configured to receive an output from diagnostic circuit 235 (or other circuitry of or associated with circuit board 230) indicative of power flow through or associated with power cable 282 and/or power cable 292 in combination or conjunction with output indicative of a fault of power cable 282 and/or power cable 292. In response to receiving such output, controller 212 may determine, output, and/or execute a magnitude or degree of derating to perform up to and including disabling, disconnecting, or shutting down ECU 220 or one or more components of circuit board 230, or combinations thereof. Additionally or alternatively, controller 212 may be configured to evaluate a number of occurrences of output indicative of a fault of power cable 282 and/or power cable 292 and utilize such information in combination with or in place of indicative of power flow through or associated with power cable 282 and/or power cable 292 to determine, output, and/or execute a magnitude or degree of derating to perform up to and including disabling, disconnecting, or shutting down ECU 220 or one or more components of circuit board 230, or combinations thereof.

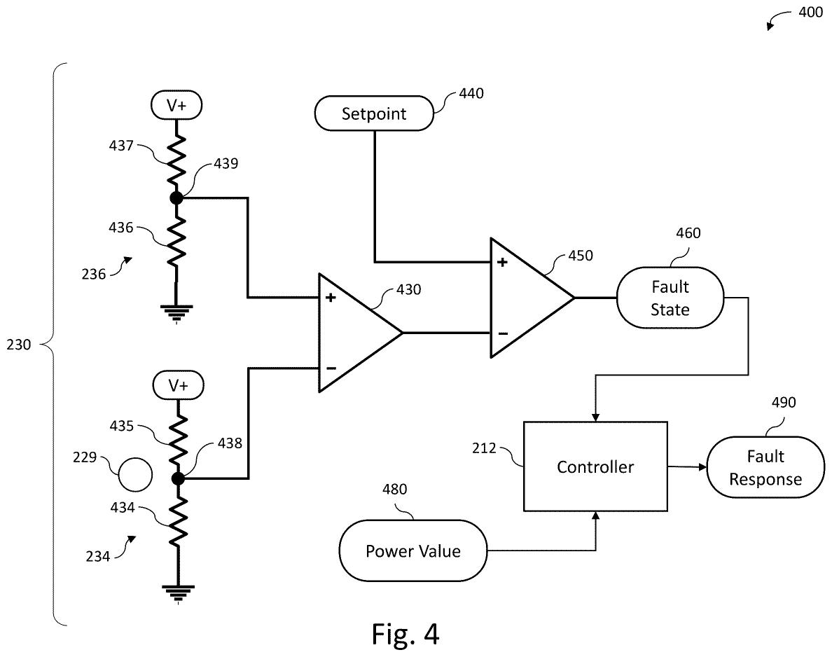

With reference to FIG. 4, there is illustrated diagnostic circuit 400 (also referred to herein as circuit 400). Circuit 400 is one example of a diagnostic circuit which is configured and operable to perform ECU power cable fault detection. It shall be appreciated that a cable fault may comprise a number of conditions of an ECU power cable including, for example, crimp degradation or failure, other connection degradation or failure, insulation degradation or failure, and/or conductor degradation or failure.

Circuit 400 depicts an example implementation of temperature sensor 234. In the illustrated example, temperature sensor 234 includes thermistor 434 and biasing resistor 435. Biasing resistor 435 is coupled with a voltage V+and thermistor 434. Thermistor 434 is coupled with biasing resistor 435 and ground. A node 438 intermediate thermistor 434 and biasing resistor 435 is coupled with an input of comparator 430. Temperature sensor 234 is configured to provide a voltage at node 438 as an input to comparator 430 indicative of a temperature of terminal 229.

Circuit 400 depicts an example implementation of temperature sensor 236. In the illustrated example, temperature sensor 236 includes thermistor 436 and biasing resistor 437. Biasing resistor 437 is coupled with a voltage V+and thermistor 436. Thermistor 436 is coupled with biasing resistor 437 and ground. A node 439 intermediate thermistor 436 and biasing resistor 437 is coupled with an input of comparator 430. Temperature sensor 236 is configured to provide a voltage at node 439 as an input to comparator 430 indicative of temperature of an operating environment of circuit board 230.

Comparator 430 is configured and operable to provide an output indicative of a difference between the temperature of terminal 229 temperature of an operating environment of circuit board 230. The output of comparator 430 is provided to an input of comparator 450. Another input of comparator 450 is configured to receive setpoint 440. Setpoint 440 comprises a threshold parameter which may be determined and configured for particular use cases or embodiments based on failure analysis and data indicating a limit on permissible different between difference between the temperature of terminal 229 temperature of an operating environment of circuit board 230 or a difference indicating a power cable fault.

Comparator 450 is configured and operable to provide an output 460 indicative of a presence or absence of a fault of power cable 292 which is operatively coupled with terminal 229 in response to output of comparator 430 and setpoint 440. A first value of output 460 may indicate presence of such as fault and second value of output 460 differing from the first value may indicate absence of such a fault.

It shall be appreciated that comparator 430 and/or comparator 450 may be configured and provide in a number of forms. In some forms, comparator 430 and/or comparator 450 may be configured and provided in a microcontroller via processing circuitry configured to execute instructions stored in one or more non-transitory memory media. In some forms, comparator 430 and/or comparator 450 may be configured and provided as discrete integrated circuit devices mounted on circuit board 230.

Output 460 is provided as input to controller 212. Power value 480 is also provided as input to controller 212. Power value 480 comprises an example of a power parameter indicative of power transmitted through the power cable 292 at a time corresponding output 460 and the inputs to comparator 430 and comparator 450. Controller 212 is configured to determine, evaluate, output, and or execute fault response 490 which may comprise any of the fault responses or combinations of fault responses described herein.

It shall be appreciated that additional diagnostic circuits substantially the same as or similar to circuit 400 may be provided on circuit board 230. For example, a substantially similar diagnostic circuit may be provided for diagnosis of terminal 229 and power cable 292. Other substantially similar diagnostic circuits may be provided for other power terminals and power cables associated with circuit board 230 and ECU 220 or other circuit boards and other ECUs.

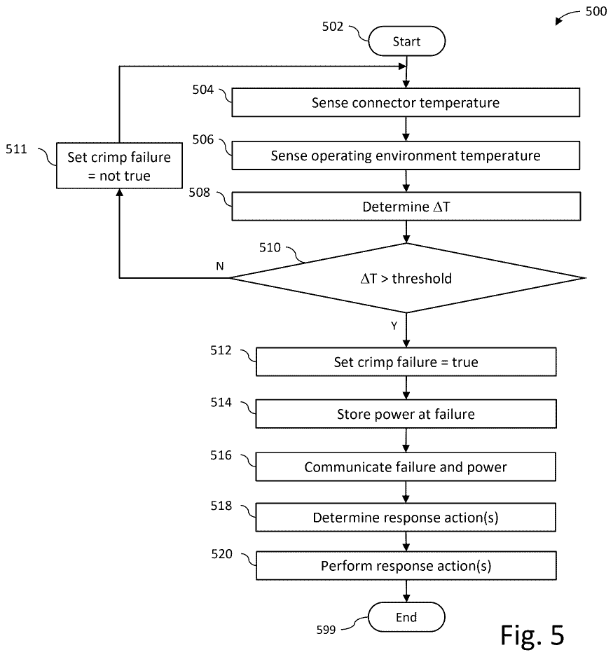

With reference to FIG. 5, there is illustrated an example process 500 which is configured and operable to perform ECU power cable fault detection. Process 500 may be implemented and executed in connection with system 200 and circuit 400 or in connection with other systems and circuits. It shall be further appreciated that the operations of process 500 may be performed and executed using the components, devices, systems and techniques described herein in connection with system 200 and circuit 400.

Process 500 begins at start operation 502 and proceeds to operation 504 which senses a connector temperature. From operation 504, process 500 proceeds to operation 506 which senses an operating environment temperature. From operation 506, process 500 proceeds to operation 508, which determines a temperature difference between the connector temperature and the operating environment temperature. From operation 508, process 500 proceeds to conditional 510 which evaluates whether the temperature difference is greater than a predetermined value. If conditional 510 evaluates negative, process 500 proceeds to operation 511 which sets a cable fault parameter equal to not true. From operation 511, process 500 returns to operation 504 proceeds as described above.

If conditional 510 evaluates affirmative, process 500 proceeds to operation 512 which sets a cable fault parameter equal to true. From operation 512, process 500 proceeds to operation 514 which obtains a power at failure value corresponding to power through a power cable at the time of the cable fault associated with operation 512 setting a cable fault parameter equal to true. From operation 514, process 500 proceeds to operation 516 which communicates the cable fault parameter and the power parameter to a controller. From operation 516, process 500 proceeds to operation 518 which determines one or more response actions in response to the cable fault. From operation 518, process 500 proceeds to operation 520 performs one or more response actions. From operation 520, process 500 proceeds to end operation 599 and may thereafter be repeated.

As shown by this detailed description, the present disclosure contemplates multiple and various embodiments, including, without limitation, the following example embodiments.

Example embodiment number 1 is a system comprising: an electronic control unit (ECU) including a housing, a circuit board disposed in the housing, and a power terminal conductively coupled with the circuit board and accessible from an exterior of the housing; a power cable operatively coupled with the power terminal and with one of a power supply and a load, the power cable including a terminal connector mechanically and conductively coupled with a jacketed conductor and conductively coupled with the power terminal; a first temperature sensor configured to sense a first temperature indicative of temperature of the power terminal; a second temperature sensor configured to sense a second temperature indicative of temperature of an operating environment of the circuit board; a diagnostic circuit configured receive output of the first temperature sensor and output of the second temperature sensor and to provide output indicating presence or absence of a fault of the power cable in response to a difference between the output of the first temperature sensor and the output of the second temperature sensor; and a controller configured to change operation of the ECU in response to the output of the diagnostic circuit.

Example embodiment number 2 includes the features of example embodiment number 1, wherein the diagnostic circuit includes a first comparator configured to provide a first output in response to the first temperature and the second temperature.

Example embodiment number 3 includes the features of example embodiment number 2, wherein the diagnostic circuit includes a second comparator configured to provide the output indicating presence or absence of a fault of the power cable in response to output of the first comparator and a threshold parameter.

Example embodiment number 4 includes the features of example embodiment number 3, wherein the controller is configured to derate power transmitted by the power cable in response to output of the second comparator.

Example embodiment number 5 includes the features of example embodiment number 3, wherein the controller is configured selectably derate power transmitted by the power cable in response to output of the second comparator and a power parameter associated with the output of the second parameter and indicative of power transmitted through the power cable.

Example embodiment number 6 includes the features of example embodiment number 1, wherein the diagnostic circuit comprises at least in part in a microcontroller mounted on the circuit board.

Example embodiment number 7 includes the features of example embodiment number 1, wherein the diagnostic circuit comprises at least in part one or more discrete integrated circuit mounted on the circuit board.

Example embodiment number 8 includes the features of example embodiment number 1, wherein the first temperature sensor comprises a thermistor mounted on the circuit board at a first location proximate the power terminal.

Example embodiment number 9 includes the features of example embodiment number 1, wherein the second temperature sensor comprises a thermistor mounted on the circuit board at a second location thermally insulated from the power terminal.

Example embodiment number 10 includes the features of example embodiment number 1, wherein the electronic control unit (ECU) is configured as a heater control unit (HCU) of a powertrain system.

Example embodiment number 11 is a process comprising: operating an electronic control system including an electronic control unit (ECU) including a housing, a circuit board disposed in the housing, and a power terminal conductively coupled with the circuit board and accessible from an exterior of the housing, and a power cable operatively coupled with the power terminal and one of a power supply and a load, the power cable including a terminal connector mechanically and conductively coupled with a jacketed conductor and conductively coupled with the power terminal, the operating including sensing with a first temperature sensor a first temperature indicative of temperature of the power terminal; sensing with a second temperature sensor a second temperature indicative of temperature of an operating environment of the circuit board; providing with a diagnostic circuit operatively coupled with the first temperature sensor and the second temperature sensors output indicative of presence or absence of a fault of the power cable in response to a in response to a difference between the first temperature and the second temperature; modifying operation of the ECU with a controller in response to the output indicative of presence or absence of a fault of the power cable.

Example embodiment number 12 includes the features of example embodiment number 11, wherein the providing comprises providing first output of a first comparator in response to the first temperature and the second temperature.

Example embodiment number 13 includes the features of example embodiment number 12, wherein the providing output comprises providing second output of a second comparator in response to the first output of the first comparator and a threshold parameter, the second output indicating presence or absence of a fault of the power cable.

Example embodiment number 14 includes the features of example embodiment number 13, wherein the modifying operation of the ECU comprises derating power transmitted by the power cable.

Example embodiment number 15 includes the features of example embodiment number 13, wherein the modifying operation of the ECU comprises selectably derating power transmitted by the power cable in response to output of the second comparator and a power parameter associated with the output of the second parameter and indicative of power transmitted through the power cable.

Example embodiment number 16 includes the features of example embodiment number 11, wherein the diagnostic circuit comprises at least in part in a microcontroller mounted on the circuit board.

Example embodiment number 17 includes the features of example embodiment number 11, wherein the diagnostic circuit comprises at least in part one or more discrete integrated circuit mounted on the circuit board.

Example embodiment number 18 includes the features of example embodiment number 11, wherein the first temperature sensor comprises a thermistor mounted on the circuit board at a first location proximate the power terminal.

Example embodiment number 19 includes the features of example embodiment number 11, wherein the second temperature sensor comprises a thermistor mounted on the circuit board at a second location thermally insulated from the power terminal.

Example embodiment number 20 includes the features of example embodiment number 11, wherein the process is performed at least in part of an electronic control system of a vehicle system.

It shall be appreciated that terms such as “a non-transitory memory,” “a non-transitory memory medium,” and “a non-transitory memory device” refer to a number of types of devices and storage mediums which may be configured to store information, such as data or instructions, readable or executable by a processor or other components of a computer system and that such terms include and encompass a single or unitary device or medium storing such information, multiple devices or media across or among which respective portions of such information are stored, and multiple devices or media across or among which multiple copies of such information are stored.

It shall be appreciated that terms such as “determine,” “determined,” “determining” and the like when utilized in connection with a control method or process, an electronic control system or controller, electronic controls, or components or operations of the foregoing refer inclusively to a number of acts, configurations, devices, operations, and techniques including, without limitation, calculation or computation of a parameter or value, obtaining a parameter or value from a lookup table or using a lookup operation, receiving parameters or values from a datalink or network communication, receiving an electronic signal (e.g., a voltage, frequency, current, or pulse-width modulation (PWM) signal) indicative of the parameter or value, receiving output of a sensor indicative of the parameter or value, receiving other outputs or inputs indicative of the parameter or value, reading the parameter or value from a memory location on a computer-readable medium, receiving the parameter or value as a run-time parameter, and/or by receiving a parameter or value by which the interpreted parameter can be calculated, and/or by referencing a default value that is interpreted to be the parameter value.

While example embodiments of the disclosure have been illustrated and described in detail in the drawings and foregoing description, the same is to be considered as illustrative and not restrictive in character, it being understood that only certain example embodiments have been shown and described and that all changes and modifications that come within the spirit of the claimed inventions are desired to be protected. It should be understood that while the use of words such as preferable, preferably, preferred or more preferred utilized in the description above indicates that the feature so described may be more desirable, it nonetheless may not be necessary and embodiments lacking the same may be contemplated as within the scope of the invention, the scope being defined by the claims that follow. In reading the claims, it is intended that when words such as “a,” “an,” “at least one,” or “at least one portion” are used there is no intention to limit the claim to only one item unless specifically stated to the contrary in the claim. When the language “at least a portion” and/or “a portion” is used the item can include a portion and/or the entire item unless specifically stated to the contrary.

What is claimed is:

1. A system comprising:
an electronic control unit (ECU) including a housing, a circuit board disposed in the housing, and a power terminal conductively coupled with the circuit board and accessible from an exterior of the housing;
a power cable operatively coupled with the power terminal and with one of a power supply and a load, the power cable including a terminal connector mechanically and conductively coupled with a jacketed conductor and conductively coupled with the power terminal;
a first temperature sensor configured to sense a first temperature indicative of temperature of the power terminal;
a second temperature sensor configured to sense a second temperature indicative of temperature of an operating environment of the circuit board;
a diagnostic circuit configured receive output of the first temperature sensor and output of the second temperature sensor and to provide output indicating presence or absence of a fault of the power cable in response to a difference between the output of the first temperature sensor and the output of the second temperature sensor; and
a controller configured to change operation of the ECU in response to the output of the diagnostic circuit.

2. The system of claim 1, wherein the diagnostic circuit includes a first comparator configured to provide a first output in response to the first temperature and the second temperature.

3. The system of claim 2, wherein the diagnostic circuit includes a second comparator configured to provide the output indicating presence or absence of a fault of the power cable in response to output of the first comparator and a threshold parameter.

4. The system of claim 3, wherein the controller is configured to derate power transmitted by the power cable in response to output of the second comparator.

5. The system of claim 3, wherein the controller is configured selectably derate power transmitted by the power cable in response to output of the second comparator and a power parameter associated with the output of the second parameter and indicative of power transmitted through the power cable.

6. The system of claim 1, wherein the diagnostic circuit comprises at least in part in a microcontroller mounted on the circuit board.

7. The system of claim 1, wherein the diagnostic circuit comprises at least in part one or more discrete integrated circuit mounted on the circuit board.

8. The system of claim 1, wherein the first temperature sensor comprises a thermistor mounted on the circuit board at a first location proximate the power terminal.

9. The system of claim 1, wherein the second temperature sensor comprises a thermistor mounted on the circuit board at a second location thermally insulated from the power terminal.

10. The system of claim 1, wherein the electronic control unit (ECU) is configured as a heater control unit (HCU) of a powertrain system.

11. A process comprising:
operating an electronic control system including an electronic control unit (ECU) including a housing, a circuit board disposed in the housing, and a power terminal conductively coupled with the circuit board and accessible from an exterior of the housing, and a power cable operatively coupled with the power terminal and one of a power supply and a load, the power cable including a terminal connector mechanically and conductively coupled with a jacketed conductor and conductively coupled with the power terminal, the operating including sensing with a first temperature sensor a first temperature indicative of temperature of the power terminal;
sensing with a second temperature sensor a second temperature indicative of temperature of an operating environment of the circuit board;
providing with a diagnostic circuit operatively coupled with the first temperature sensor and the second temperature sensors output indicative of presence or absence of a fault of the power cable in response to a in response to a difference between the first temperature and the second temperature;
modifying operation of the ECU with a controller in response to the output indicative of presence or absence of a fault of the power cable.

12. The process of claim 11, wherein the providing comprises providing first output of a first comparator in response to the first temperature and the second temperature.

13. The process of claim 12, wherein the providing output comprises providing second output of a second comparator in response to the first output of the first comparator and a threshold parameter, the second output indicating presence or absence of a fault of the power cable.

14. The process of claim 13, wherein the modifying operation of the ECU comprises derating power transmitted by the power cable.

15. The process of claim 13, wherein the modifying operation of the ECU comprises selectably derating power transmitted by the power cable in response to output of the second comparator and a power parameter associated with the output of the second parameter and indicative of power transmitted through the power cable.

16. The process of claim 11, wherein the diagnostic circuit comprises at least in part in a microcontroller mounted on the circuit board.

17. The process of claim 11, wherein the diagnostic circuit comprises at least in part one or more discrete integrated circuit mounted on the circuit board.

18. The process of claim 11, wherein the first temperature sensor comprises a thermistor mounted on the circuit board at a first location proximate the power terminal.

19. The process of claim 11, wherein the second temperature sensor comprises a thermistor mounted on the circuit board at a second location thermally insulated from the power terminal.

20. The process of claim 11, wherein the process is performed at least in part of an electronic control system of a vehicle system.
